(19) United States
(12) Patent Application Publication
(10) Pub. No.: US 2010/0259984 A1
(43) Pub. Date: Oct. 14, 2010

(54) ERASE METHOD OF NONVOLATILE SEMICONDUCTOR MEMORY DEVICE

(75) Inventor: Hidenori TAKEUCHI, Kanagawa (JP)

Correspondence Address: YOUNG & THOMPSON, 209 Madison Street, Suite 500, Alexandria, VA, 22314, US

(73) Assignee: NEC ELECTRONICS CORPORATION, Kanagawa (JP)

(21) Appl. No.: 12/752,573

(22) Filed: Apr. 1, 2010

(30) Foreign Application Priority Data
Apr. 8, 2009 (JP) 2009-093894

(51) Int. Cl. G11C 16/04

(52) U.S. Cl. 365/185.15; 365/185.29

(57) ABSTRACT

An erase method of a nonvolatile semiconductor memory device including a semiconductor substrate with diffusion regions spaced from each other, a first insulating layer formed on the semiconductor substrate, a first gate electrode formed in a first area on the first insulating layer, a charge accumulation layer formed in a second area on the first insulating layer, a second insulating layer formed on the charge accumulation layer and a second gate electrode formed on the second insulating layer includes a step of injecting hot holes into the charge accumulation layer from the diffusion region and a step of injecting channel hot electrons into a part of the charge accumulation layer close to the first gate electrode side.

### INCORPORATION BY REFERENCE

This application is based upon and claims the benefit of priority from Japanese patent application No. 2009-093894, filed on Apr. 8, 2009, the disclosure of which is incorporated herein in its entirety by reference.

### BACKGROUND

1. Field of the Invention

The present invention relates to an erase method of a nonvolatile semiconductor memory device and, particularly, to an erase method of a charge trap nonvolatile semiconductor memory device.

2. Description of Related Art

A metal-oxide-nitride-oxide-semiconductor (MONOS) memory cell, which is a charge trap nonvolatile semiconductor memory element, has a structure in which an oxide film as a first potential barrier insulating layer called a bottom oxide film, a nitride film as a charge accumulation layer, and an oxide film as a second potential barrier insulating layer called a top oxide film are sequentially placed on a semiconductor substrate. Further, a gate electrode is placed thereon. On the surface of the semiconductor substrate, source and drain impurity diffusion regions with the conductivity type opposite to that of the substrate are formed. When writing to the MONOS memory cell, negative charges (electrons) are injected into the nitride film having charge storage capacity from the semiconductor substrate. Further, when erasing, negative charges accumulated in the nitride film as the charge accumulation layer are neutralized, and then positive charges (holes) are injected into the nitride film. Japanese Unexamined Patent Application Publication No. 2005-277032 discloses a technique related to such a MONOS memory element.

FIG. 11A is a sectional view showing a twin MONOS cell, which is one of the MONOS memory element. In FIG. 11A, impurity diffusion regions 102 and 103, which serve as source and drain regions, are formed spaced from each other in the surface area of a semiconductor substrate 101. FIG. 11B is a view showing the vicinity of a first control gate electrode 104 in an enlarged scale. In FIG. 11B, a first oxide film (SiO₂) 107 on the bottom side as a potential barrier, a nitride film (SiN) 108, and a second oxide film (SiO₂) 109 on the top side as a potential barrier are sequentially placed on the semiconductor substrate 101. The nitride film 108 functions as a charge accumulation layer. On the second oxide film 109, the first control gate electrode 104 is placed. The second oxide film and the control gate electrode are formed on the respective impurity diffusion regions (source side and drain side) 102 and 103 of the semiconductor substrate 101. Further, a word gate electrode 105 is placed between the first control gate electrode 104 and a second control gate electrode 106, with a silicon oxide film formed at a channel central part on the semiconductor substrate 101 interposed therebetween.

The word gate electrode 105 is connected to a word line (not shown). The control gate electrodes 104 and 106 are arranged in the direction parallel to the word line and controlled independently of the word gate electrode 105. Such a twin MONOS cell is disclosed in Japanese Unexamined Patent Application Publication No. 2002-289711.

In the twin MONOS cell, in the case of erase operation, voltages WG, CG1, CG2, BL1 and BL2 of the respective electrodes are set as shown in FIG. 11A, and thereby hot holes (positive charges) are injected into the respective nitride films under the first control gate electrode 104 and the second control gate electrode 106 from the impurity diffusion regions 102 and 103. At this time, the holes are trapped in the nitride film 108 across the first oxide film 107 which is a potential barrier on the bottom side as shown in FIG. 11B. The injection of hot holes is performed to erase the memory cell. As a result that the holes are trapped in the nitride film 108, positive charges in the control gate become higher, and a voltage threshold under the control gate becomes lower. The erase operation (injection of hot holes) in the memory cell is performed repeatedly until the read voltage threshold becomes low enough.

FIG. 11C shows carrier density distribution (distribution 120 of holes) in the nitride film 108 after such repeated erasing. The positional relationship of WG and BL in FIG. 11C corresponds to the positional relationship of WG and BL in FIG. 11B.

Next, write operation of the twin MONOS cell is described hereinafter with reference to FIG. 12. In the case of write operation, the voltages WG, CG1, CG2, BL1 and BL2 of the respective electrodes are set as shown in FIG. 12A, and thereby channel hot electrons (electrons) are injected into the nitride film 108 under the first control gate electrode 104 from the impurity diffusion region 103. At this time also, the electrons are trapped in the nitride film 108 across the first oxide film 107 as shown in FIG. 12B. If the state of the memory cell before writing is in an erase state, a large number of holes already exist in the nitride film 108, and the holes and the electrons are recombined and cancelled out and neutralized. Then, electrons are further injected into the nitride film 108, and thereby the charges in the nitride film 108 under the control gate electrode 104 become negative, and a voltage threshold under the control gate becomes higher. The write operation in the memory cell is performed repeatedly until the read voltage threshold becomes high enough.

FIG. 12C shows carrier density distribution (distribution 121 of electrons) in the nitride film 108 after such repeated writing. The positional relationship of WG and BL in FIG. 12C corresponds to the positional relationship of WG and BL in FIG. 12B.

### SUMMARY

FIG. 13 is a view to describe the case where the distribution 120 of holes in the nitride film 108 after repeated erasing shown in FIG. 11C and the distribution 121 of electrons in the nitride film 108 after repeated writing shown in FIG. 12C are matched. As shown in FIG. 13, the injection position, distribution width or the like of holes and electrons is different between the hole distribution 120 at the time of erasing and the electron distribution 121 at the time of writing. If the distribution of holes and electrons is different, excess hole distributions 130 and 131 appear at both ends of the electron distribution 121 after matching holes and electrons, i.e. the position on the word gate side, the position on the bit line side and so on as shown in FIG. 13. In the excess hole distributions 130 and 131, the carrier density increases by repeating of write operation and erase operation in the memory cell.

Although the effect of the hole distribution in those positions on the threshold voltage of the memory cell is relatively small, if the memory cell is stored under high temperature conditions, for example, excess holes move to the electron distribution side of a write cell and are recombined with electrons, thus decreasing electrons in the write cell itself. By such a phenomenon, the threshold voltage of the control gate at the time of reading to the memory cell becomes lower, causing degradation of the retention characteristics of the memory cell.

An exemplary aspect of the present invention is an erase method of a nonvolatile semiconductor memory device including a semiconductor substrate with diffusion regions spaced from each other, a first insulating layer formed on the semiconductor substrate, a first gate electrode formed in a first area on the first insulating layer, a charge accumulation layer formed in a second area on the first insulating layer, a second insulating layer formed on the charge accumulation layer, and a second gate electrode formed on the second insulating layer, which includes step of injecting hot holes into the charge accumulation layer from the diffusion region, and injecting channel hot electrons into a part of the charge accumulation layer close to the first gate electrode side.

In this exemplary aspect of the present invention, hot holes are injected into the charge accumulation layer and electrons are injected into the position where excess holes are formed during erase operation of the nonvolatile semiconductor memory device, thus reducing formation of excess holes in the charge accumulation layer. It is thereby possible to improve the retention characteristics of the nonvolatile semiconductor memory device.

With use of the erase method of a nonvolatile semiconductor memory device according to the exemplary aspect of the present invention, it is possible to improve the retention characteristics of the nonvolatile semiconductor memory device.

### BRIEF DESCRIPTION OF THE DRAWINGS

The above and other exemplary aspects, advantages and features will be more apparent from the following description of certain exemplary embodiments taken in conjunction with the accompanying drawings, in which:

FIG. 1 is a flowchart to describe an erase method of a nonvolatile semiconductor memory device according to a first exemplary embodiment;

FIG. 2 is a sectional view showing a nonvolatile semiconductor memory device for implementing the erase method of a nonvolatile semiconductor memory device according to the first exemplary embodiment;

FIGS. 3A to 3D are views to describe a first step of the erase method of a nonvolatile semiconductor memory device according to the first exemplary embodiment, where FIG. 3A is a sectional view of the nonvolatile semiconductor memory device, FIG. 3B is an enlarged view of the vicinity of a charge accumulation layer of the nonvolatile semiconductor memory device, FIG. 3C is a distribution view of holes accumulated in the charge accumulation layer of the nonvolatile semiconductor memory device, and FIG. 3D is a view showing a force applied to a hole;

FIGS. 4A to 4D are views to describe a second step of the erase method of a nonvolatile semiconductor memory device according to the first exemplary embodiment, where FIG. 4A is a sectional view of the nonvolatile semiconductor memory device, FIG. 4B is an enlarged view of the vicinity of the charge accumulation layer of the nonvolatile semiconductor memory device, FIG. 4C is a distribution view of electrons accumulated in the charge accumulation layer of the nonvolatile semiconductor memory device, and FIG. 4D is a view showing a force applied to an electron;

FIGS. 5A to 5D are views to describe a third step of the erase method of a nonvolatile semiconductor memory device according to the first exemplary embodiment, where FIG. 5A is a sectional view of the nonvolatile semiconductor memory device, FIG. 5B is an enlarged view of the vicinity of the charge accumulation layer of the nonvolatile semiconductor memory device, FIG. 5C is a distribution view of electrons accumulated in the charge accumulation layer of the nonvolatile semiconductor memory device, and FIG. 5D is a view showing a force applied to an electron;

FIG. 6 is a view to describe distribution of holes in the charge accumulation layer in the case of using the erase method of a nonvolatile semiconductor memory device according to the first exemplary embodiment;

FIGS. 7A to 7D are views to describe write operation of the nonvolatile semiconductor memory device according to the first exemplary embodiment, where FIG. 7A is a sectional view of the nonvolatile semiconductor memory device, FIG. 7B is an enlarged view of the vicinity of the charge accumulation layer of the nonvolatile semiconductor memory device, FIG. 7C is a distribution view of electrons accumulated in the charge accumulation layer of the nonvolatile semiconductor memory device, and FIG. 7D is a view showing a force applied to an electron;

FIGS. 8A and 8B are views to describe read operation of the nonvolatile semiconductor memory device according to the first exemplary embodiment, where FIG. 8A is a view showing an example of a voltage at the time of reading in a cell on the CG1 side, and FIG. 8B is a view showing an example of a voltage at the time of reading in a cell on the CG2 side;

FIG. 9 is a flowchart to describe an erase method of a nonvolatile semiconductor memory device according to a second exemplary embodiment;

FIGS. 10A and 10B are views to describe the erase method of a nonvolatile semiconductor memory device according to the second exemplary embodiment, where FIG. 10A is an enlarged view of the vicinity of a charge accumulation layer of the nonvolatile semiconductor memory device, and FIG. 10B is a distribution view of holes and electrons accumulated in the charge accumulation layer of the nonvolatile semiconductor memory device;

FIGS. 11A to 11C are views to describe erase operation of a nonvolatile semiconductor memory device according to related art, where FIG. 11A is a sectional view of the nonvolatile semiconductor memory device; FIG. 11B is an enlarged view of the vicinity of a charge accumulation layer (nitride film 108) of the nonvolatile semiconductor memory device, and FIG. 11C is a distribution view of holes accumulated in the charge accumulation layer (nitride film 108) of the nonvolatile semiconductor memory device;

FIGS. 12A to 12C are views to describe write operation of a nonvolatile semiconductor memory device according to related art, where FIG. 11A is a sectional view of the nonvolatile semiconductor memory device, FIG. 11B is an enlarged view of the vicinity of a charge accumulation layer (nitride film 108) of the nonvolatile semiconductor memory device, and FIG. 11C is a distribution view of electrons accumulated in the charge accumulation layer (nitride film 108) of the nonvolatile semiconductor memory device; and

FIG. 13 is a view to describe a case where distribution of holes in the charge accumulation layer (nitride film 108) after repeated erasing and distribution of electrons in the charge accumulation layer (nitride film 108) after repeated writing are matched.

### DETAILED DESCRIPTION OF THE EXEMPLARY EMBODIMENTS

### First Exemplary Embodiment

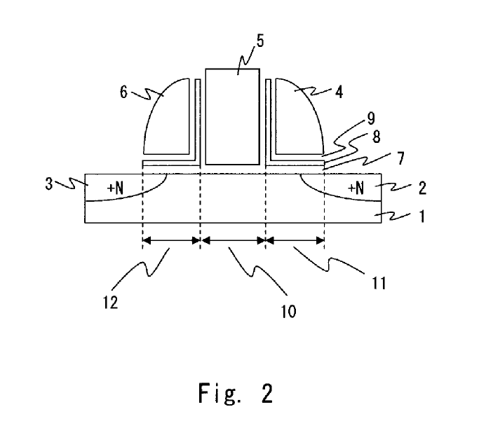

An exemplary embodiment of the present invention is described hereinafter with reference to the drawings. Firstly, a nonvolatile semiconductor memory device for implementing an erase method of a nonvolatile semiconductor memory device according to the exemplary embodiment is described hereinafter with reference to FIG. 2.

In FIG. 2, impurity diffusion regions 2 and 3, which serve as source and drain regions, are formed spaced from each other in the surface area of a semiconductor substrate 1. On the semiconductor substrate 1, a first oxide film 7 is placed to cover a channel region of the semiconductor substrate 1. As the first oxide film 7, SiO₂ is used, for example. In a first area 10 above the first oxide film 7, a first gate electrode 5 is placed. Further, in each of second areas 11 and 12 above the first oxide film 7, a charge accumulation layer 8 is placed. A nitride film is used for the charge accumulation layer 8, and SiN is used, for example. A second insulating layer 9 is placed on the charge accumulation layer 8. As the second insulating layer 9, SiO₂ is used, for example. Second gate electrodes 4 and 6 are placed on the second insulating layer 9.

Further, an insulating layer is placed respectively between the first gate electrode 5 and each of the second gate electrodes 4 and 6 in order to provide electrical isolation between those electrodes. The first gate electrode 5 is a word gate electrode (WG), and the second gate electrodes 4 and 6 are a first control gate electrode (CG1) 4 and a second control gate electrode (CG2) 6, respectively. The nonvolatile semiconductor memory device shown in FIG. 2 is a so-called twin MONOS cell.

An erase method of the nonvolatile semiconductor memory device according to the exemplary embodiment is described hereinafter.

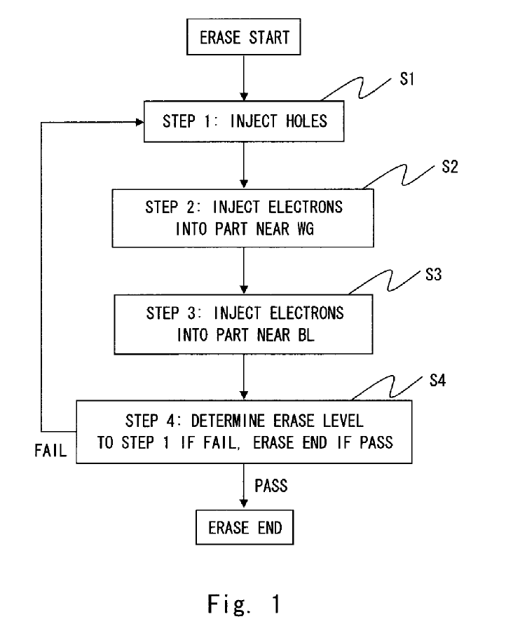

FIG. 1 is a flowchart to describe an erase method of the nonvolatile semiconductor memory device according to the exemplary embodiment. In the erase method according to the exemplary embodiment, hot holes are injected from the diffusion region (the source/drain region) to the charge accumulation layer (S1: Step 1). When injecting hot holes from the diffusion region to the charge accumulation layer, a voltage applied to the diffusion region is set to be higher than a voltage applied the second gate electrode.

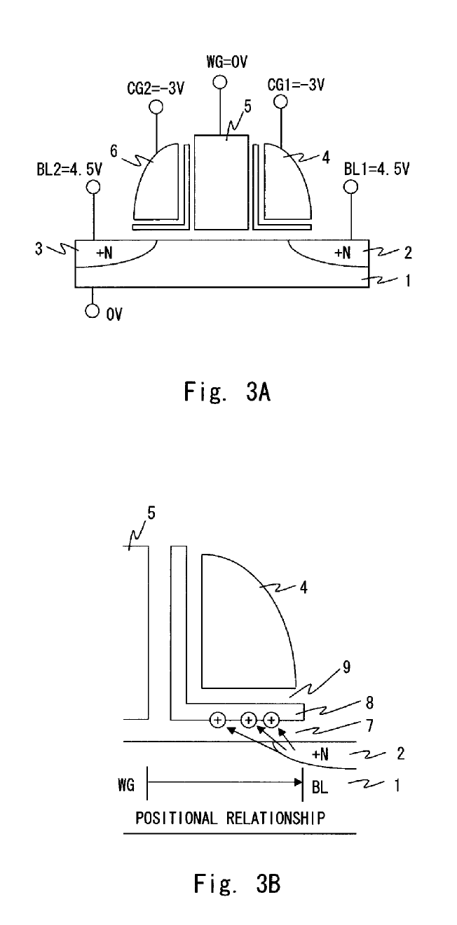

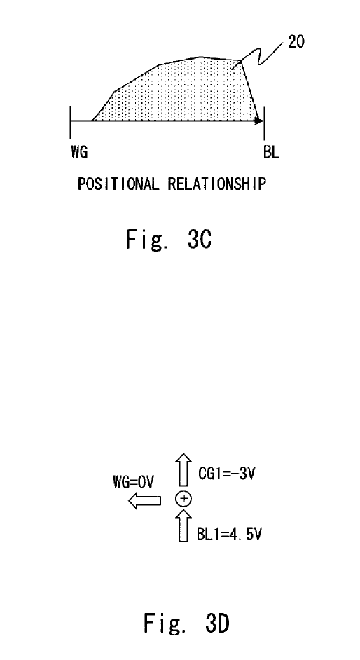

Step 1 is descried hereinafter with reference to FIG. 3. FIG. 3A is a sectional view of the nonvolatile semiconductor memory device. A voltage (WG) applied to the word gate electrode 5, a voltage (CG1) applied to the first control gate electrode 4, a voltage (CG2) applied to the second control gate electrode 6, a voltage (BL1) applied to the diffusion region 2 and a voltage (BL2) applied to the diffusion region 3 are set as shown in FIG. 3A, for example. By setting CG1=−3V and BL1=4.5V, an electric field as shown in FIG. 3D acts on holes, so that an upward force is applied to holes. As a result that such a force is applied to holes, hot holes are injected from the diffusion region 2 to the charge accumulation layer 8. The holes are trapped in the nitride film 8 across the first insulating layer 7.

FIG. 3C shows a distribution view of holes accumulated in the charge accumulation layer 8 by injection of hot holes in Step 1 (20 denotes distribution of holes). Note that the positional relationship of WG and BL in FIG. 3C corresponds to the positional relationship of WG and BL in FIG. 3B. In this case, the voltages WG, CG1 and BL1 are set so that the center of distribution of holes is near the middle of WG and BL. Further, a pulse width (time to apply a voltage) when injecting hot holes in Step 1 is set to a pulse width at the same level (e.g. about 10 ms) as that in normal erasing.

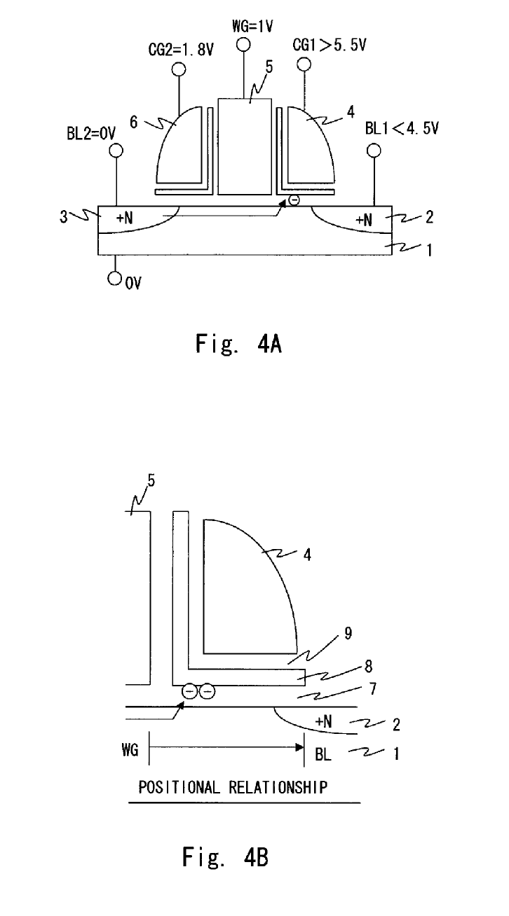

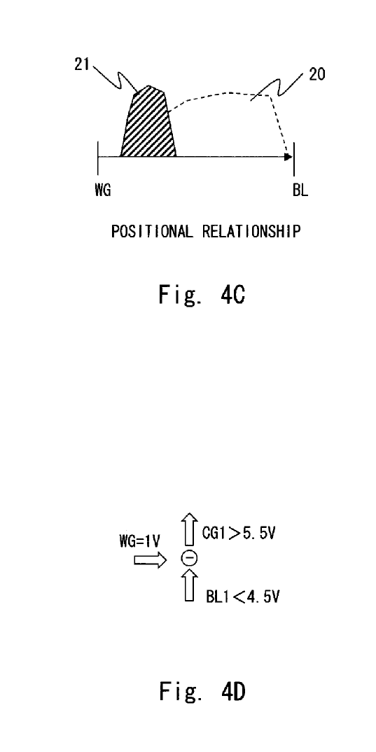

Hereinafter, Step 2 of the erase method of the nonvolatile semiconductor memory device according to the exemplary embodiment is described with reference to FIG. 4. In Step 2, weak writing, i.e. injection of electrons, is performed into the part of the charge accumulation layer 8 on the word gate electrode (first gate electrode) side (S2 in FIG. 1). FIG. 4A is a sectional view of the nonvolatile semiconductor memory device. The voltage (WG) applied to the word gate electrode 5, the voltage (CG1) applied to the first control gate electrode 4, the voltage (CG2) applied to the second control gate electrode 6, the voltage (BL1) applied to the diffusion region (i.e. the drain region) 2 and the voltage (BL2) applied to the diffusion region (i.e. the source region) 3 are set as shown in FIG. 4A, for example. By setting WG=1V, CG1>5.5V and BL1<4.5V, an electric field as shown in FIG. 4D acts on electrons, so that an upward force is applied to electrons. As a result that such a force is applied to electrons, channel hot electrons are injected into the charge accumulation layer 8 from the source region 3 (it is the source region 3 because electrons are emitted in this case) as shown in FIG. 4B. The electrons are trapped in the nitride film 8 across the first insulating layer 7.

FIG. 4C shows a distribution view of electrons accumulated in the charge accumulation layer 8 by injection of electrons in Step 2 (21 denotes distribution of electrons). In this case, by setting the voltage relationship of CG1 and BL1 as described above, the injection position of electrons can be shifted from the center to the position close to the word gate electrode (WG). Specifically, as a potential difference between CG1 and BL1 is larger, an upward force is applied to electrons more strongly, and thus electrons emitted from the source 3 are accumulated in the charge accumulation layer 8 at the position closer to WG. In theory, electrons can be injected into the position closer to WG by strengthening an upward force and weakening a crosswise (rightward) force.

By changing the set voltages WG, CG1 and BL1 in this manner, a distribution state of electrons injected into the charge accumulation layer 8 can be changed.

Further, a pulse width when injecting electrons in Step 2 is set to be shorter (e.g. 20 μs or less) than the normal write time so that the distribution of holes formed in Step 1 does not largely vary.

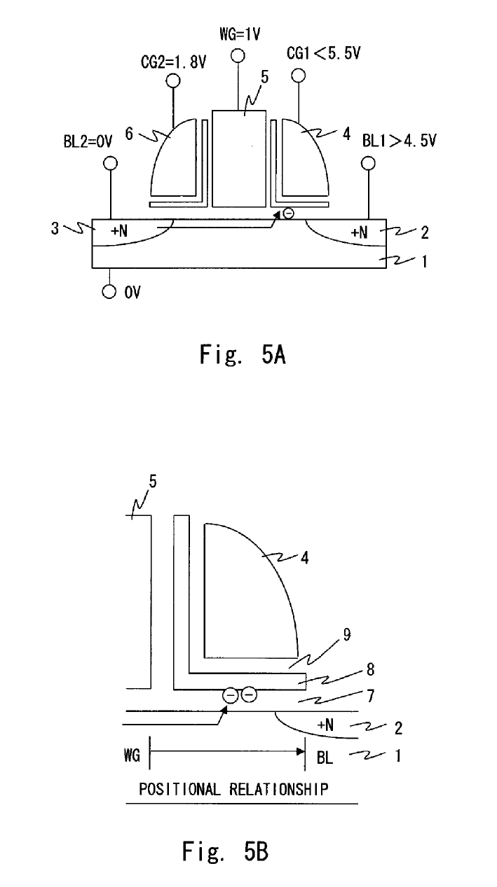

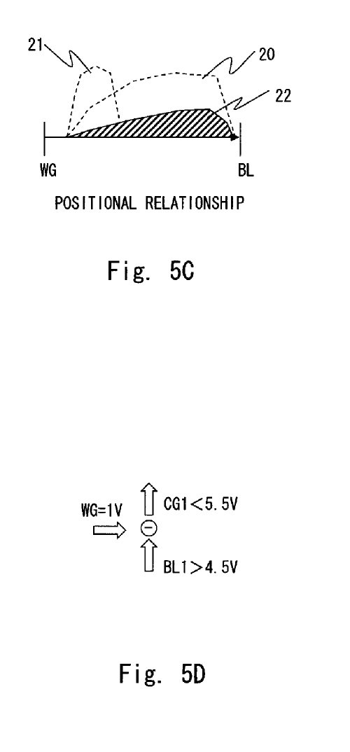

Further, Step 3 of the erase method of the nonvolatile semiconductor memory device according to the exemplary embodiment is described with reference to FIG. 5. In Step 3, weak writing, i.e. injection of electrons, is performed into the part of the charge accumulation layer 8 on the drain region side (on the BL side) (S3 in FIG. 1). FIG. 5A is a sectional view of the nonvolatile semiconductor memory device. The voltage (WG) applied to the word gate electrode 5, the voltage (CG1) applied to the first control gate electrode 4, the voltage (CG2) applied to the second control gate electrode 6, the voltage (BL1) applied to the diffusion region (i.e. the drain region) 2 and the voltage (BL2) applied to the diffusion region (i.e. the source region) 3 are set as shown in FIG. 5A, for example. By setting WG=1V, CG1<5.5V and BL1>4.5V, an electric field as shown in FIG. 5D acts on electrons, so that a crosswise force is applied to electrons by the positional effect of BL1. Note that the voltage relationship of CG1 and BL1 is CG1>BL1 because electrons are injected into the charge accumulation layer 8. As a result that such a force is applied to electrons, channel hot electrons are injected into the charge accumulation layer 8 from the source region 3 (it is the source region 3 because electrons are emitted in this case) as shown in FIG. 5B. The electrons are trapped in the nitride film 8 across the first insulating layer 7.

FIG. 5C shows a distribution view of electrons accumulated in the charge accumulation layer 8 by injection of electrons in Step 3 (22 denotes distribution of electrons). In this case, by setting the voltage relationship of CG1 and BL1 as described above, the injection position of electrons can be shifted from the center to the position close to BL (i.e. the position close to the drain region 2). Specifically, as a potential difference between CG1 and BL1 is smaller, an upward force is applied to electrons less strongly, and thus electrons emitted from the source region 3 are accumulated in the charge accumulation layer 8 at the position closer to BL. In theory, electrons can be injected into the position closer to BL by weakening an upward force and strengthening a crosswise (rightward) force.

By changing the set voltages WG, CG1 and BL1 in this manner, a distribution state of electrons injected into the charge accumulation layer 8 can be changed. Specifically, by setting a difference between the voltage (BL1) applied to the drain region and the voltage (CG1) applied to the second gate electrode in Step 2 to be larger than a difference between the voltage (BL1) applied to the drain region and the voltage (CG1) applied to the second gate electrode in Step 3, the injection position of electrons can be controlled as described in Step 2 and Step 3.

Further, a pulse width when injecting electrons in Step 3 is set to be shorter (e.g. 20 μs or less) than the normal write time so that the distribution of holes formed in Step 1 does not largely vary.

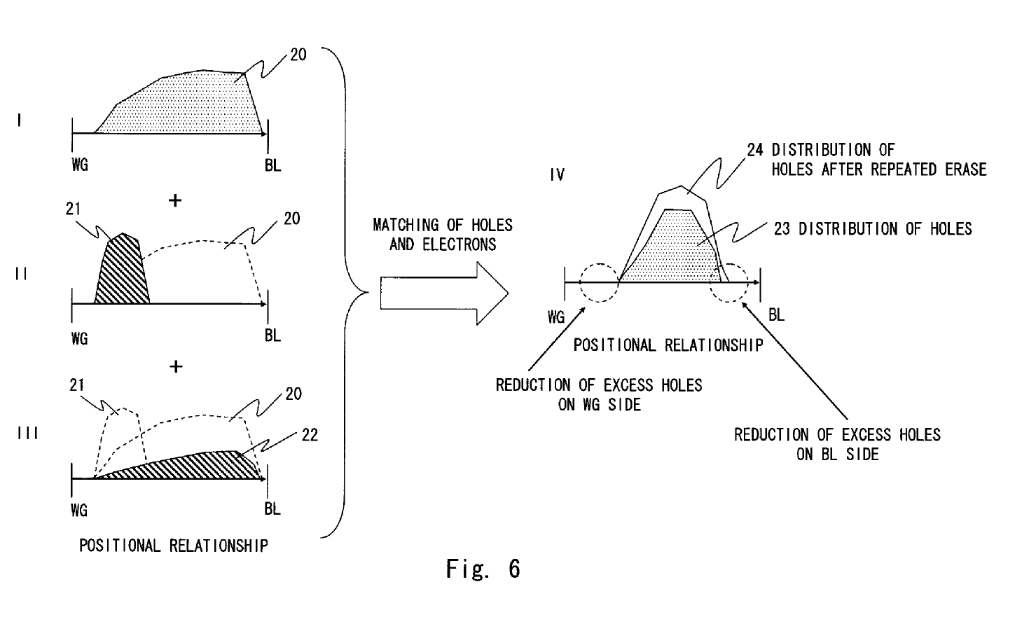

FIG. 6 is a view to describe distribution of holes and electrons by injection of hot holes in Step 1 and injection of electrons in Step 2 and Step 3.

In FIG. 6, I indicates a distribution state 20 of hot holes injected into the charge accumulation layer 8 in Step 1. In FIG. 6, II indicates a distribution state 21 of electrons injected into the charge accumulation layer 8 in Step 2. In FIG. 6, III indicates a distribution state 22 of electrons injected into the charge accumulation layer 8 in Step 3. In FIG. 6, IV indicates a distribution state 23 of holes after matching holes and electrons. Further, a distribution 24 after repeated erasing indicates a distribution state of holes after injection of hot holes in Step 1 and injection of electrons in Step 2 and Step 3 are performed repeatedly.

By injecting hot holes into the charge accumulation layer 8 (Step 1), injecting electrons into the part of the charge accumulation layer 8 close to the word gate (WG) side (Step 2), and injecting electrons into the part of the charge accumulation layer 8 close to the drain region side (BL side) (Step 3) at the time of erasing in the nonvolatile semiconductor memory device as described in the exemplary embodiment of the present invention, it is possible to reduce the excess holes generated on the WG side and the BL side in the distribution 23 of holes after erasing. It is thereby possible to improve the retention characteristics of the nonvolatile semiconductor memory device.

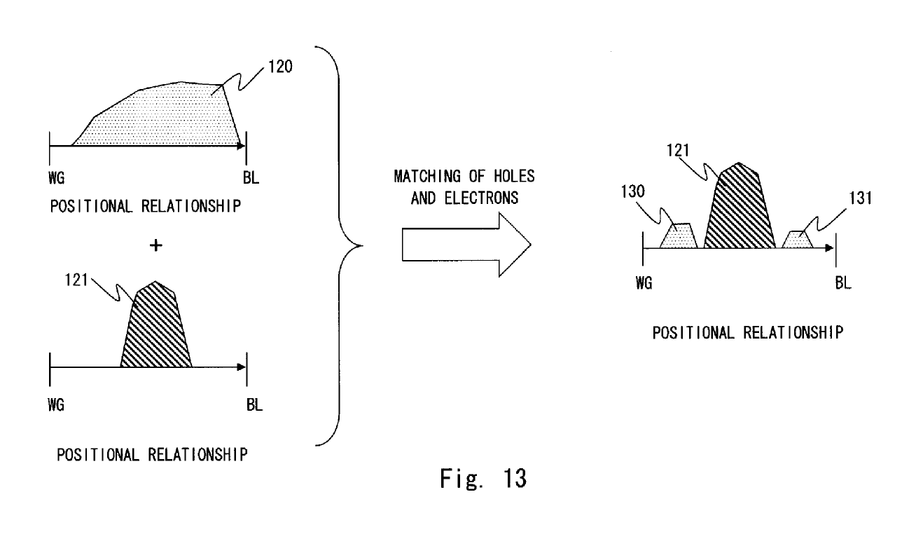

Specifically, in the erase method of the nonvolatile semiconductor memory device according to related art, the excess hole distributions 130 and 131 appear at both ends of the electron distribution 121, i.e. the positions on the WG side and the positions on the BL side as shown in FIG. 13. The excess distributions 130 and 131 of holes cause degradation of the retention characteristics of the nonvolatile semiconductor memory device.

However, by using the erase method of the nonvolatile semiconductor memory device according to the exemplary embodiment including the above-described Step 1 to Step 3, it is possible to distribute holes in such a way that the density is high at the middle of WG and BL as shown in IV in FIG. 6, thereby reducing the excess holes in the positions on the WG and BL sides.

Further, by repeatedly performing injection of hot holes in Step 1 and injection of electrons in Step 2 and Step 3 as described above, it is possible to increase the density of holes as shown in the distribution 24 of holes after repeated erasing in III of FIG. 6 and further reduce the excess holes.

Furthermore, if holes are distributed narrowly in between WG and BL as shown in III of FIG. 6, it is possible to improve the conformity with the distribution with distribution of electrons upon writing, increase the write efficiency and thereby reduce the write time. The reason that the write time is reduced is described in detail hereinbelow.

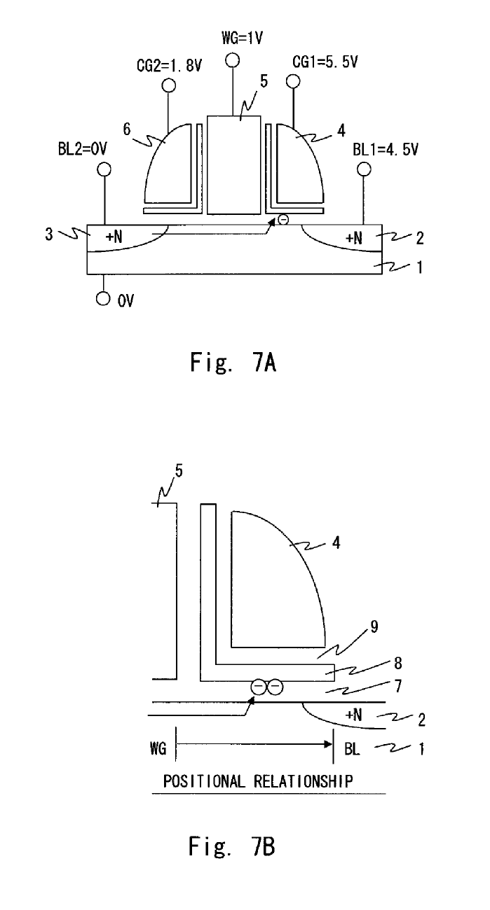

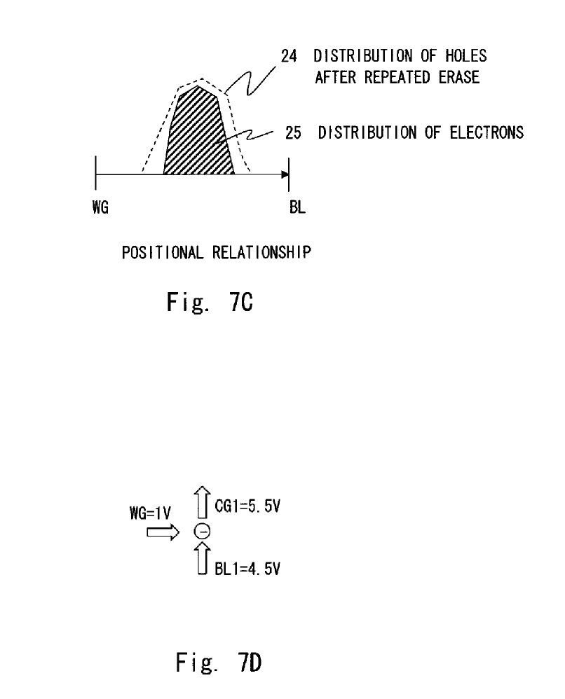

FIG. 7 is a view to describe normal write operation (write operation to memory) of the nonvolatile semiconductor memory device according to the exemplary embodiment. FIG. 7A is a sectional view of the nonvolatile semiconductor memory device. The voltage (WG) applied to the word gate electrode 5, the voltage (CG1) applied to the first control gate electrode 4, the voltage (CG2) applied to the second control gate electrode 6, the voltage (BL1) applied to the diffusion region 2 and the voltage (BL2) applied to the diffusion region 3 during normal writing are set as shown in FIG. 7A, for example. By setting CG1=5.5V, BL1=4.5V and WG=1V, an electric field as shown in FIG. 7D acts on electrons, so that an upward force is applied to electrons. As a result that such a force is applied to electrons, channel hot electrons are injected into the charge accumulation layer 8 from the source region 3 as shown in FIG. 7B. The electrons are trapped in the nitride film 8 across the first insulating layer 7.

FIG. 7C shows distribution 24 of holes after erasing by the erase method of the nonvolatile semiconductor memory device according to the exemplary embodiment and distribution 25 of electrons upon writing by voltage setting shown in FIG. 7A. By setting the injection position of electrons upon writing in such a way that the hole distribution 24 after erasing and the electron distribution 25 upon writing match as shown in FIG. 7C, the write efficiency can be improved. Specifically, by distributing holes narrowly at the middle of WG and BL and matching the distribution position of holes and the distribution position of electrons upon writing by the erase method according to the exemplary embodiment, it is possible to improve the conformity with the distribution of electrons upon writing, increase the write efficiency and thereby reduce the write time.

Hereinafter, Step 4 (S4 in FIG. 1) of the erase method of the nonvolatile semiconductor memory device according to the exemplary embodiment is described. Note that Step 4 may be omitted.

Step 4 is a step for checking whether a target erase level is reached by the erase operation of Step 1 to Step 3, and it is a step of determining charges in the charge accumulation layer 8. Determination of charges may be made by performing reading in a memory cell and making determination with a voltage threshold.

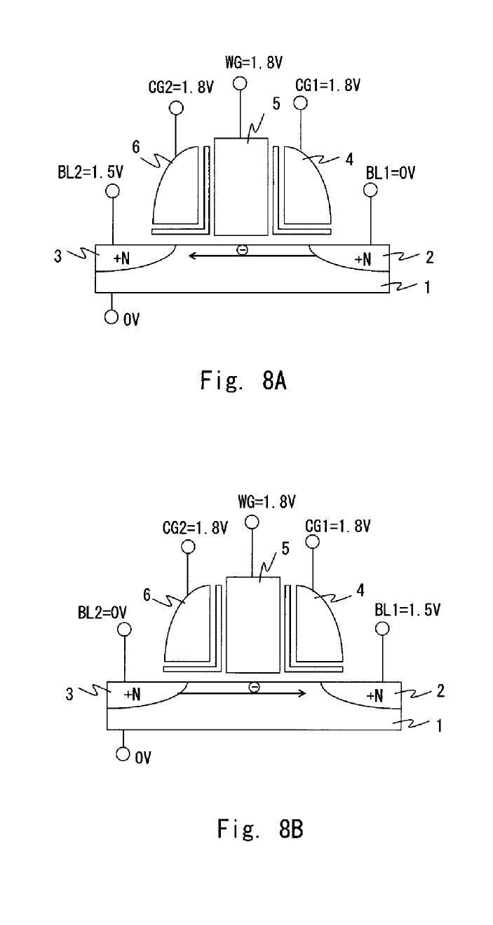

Read operation in the memory cell is described hereinafter with reference to FIGS. 8A and 8B. FIG. 8A is a view showing an example of set voltages when reading holes or electrons accumulated in the charge accumulation layer on the CG1 side. FIG. 8B is a view showing an example of set voltages when reading holes or electrons accumulated in the charge accumulation layer on the CG2 side.

FIG. 8A is described firstly. When reading holes or electrons accumulated in the charge accumulation layer on the CG1 side, voltages are set so that WG=1.8V, CG1=1.8V, CG2=1.8V, BL1=0V and BL2=1.5V as shown in FIG. 8A, for example. By setting the voltages to those values, electrons move from the source region 2 to the drain region 3. In Step 4, charges in the charge accumulation layer are determined based on a read current (Ion current) at this time.

Specifically, when the charge accumulation layer on the CG1 side reaches an erase level, namely, when a sufficient number of holes are accumulated in the charge accumulation layer, the potential of the charge accumulation layer becomes high. At this time, the number of electrons passing under the charge accumulation layer increases, and the read current in the memory cell also increases, so that a voltage threshold becomes lower.

On the other hand, when the charge accumulation layer on the CG1 side does not reach an erase level, namely, when a sufficient number of holes are not accumulated in the charge accumulation layer, the potential of the charge accumulation layer becomes low. At this time, the number of electrons passing under the charge accumulation layer decreases, and the read current in the memory cell also decreases, so that a voltage threshold becomes higher. In the case of 8B also, the read current can be obtained in the same manner as in the case of FIG. 8A.

Specifically, in Step 4, the erase level, i.e. the amount of holes accumulated in the charge accumulation layer, after performing the erase steps of Step 1 to Step 3 is determined by measuring a read current in the memory cell. If the erase level is insufficient, the process returns to Step 1 and starts the erase step again. If, on the other hand, it is determined that the erase level is sufficient, the process ends the erase work.

In the exemplary embodiment of the present invention, Step 4 is not an essential step. For example, Step 4 can be omitted by using a method that presets the number of times of repeating Step 1 to Step 3 so as to reach a sufficient erase level.

In the exemplary embodiment of the present invention described above, it is possible to reduce formation of excess holes in the charge accumulation layer by injecting hot holes into the charge accumulation layer and injecting electrons into the position where excess holes are formed during erase operation of the nonvolatile semiconductor memory device. It is thereby possible to improve the retention characteristics of the nonvolatile semiconductor memory device.

The erase method of the nonvolatile semiconductor memory device according to the exemplary embodiment is described above with regard to Step 1 to Step 4 in FIG. 1. However, in the erase method of the nonvolatile semiconductor memory device, the advantage of the present invention that improves the retention characteristics of the nonvolatile semiconductor memory device can be obtained by at least including Step 1 and Step 2.

Specifically, in the erase method of the nonvolatile semiconductor memory device according to the exemplary embodiment, formation of excess holes (in this case, excess holes 130 on the WG side) in the charge accumulation layer can be reduced by injecting hot holes into the charge accumulation layer from the diffusion region (Step 1) and injecting channel hot electrons into the part of the charge accumulation layer on the gate electrode (WG) side (Step 2), and it is thus possible to improve the retention characteristics compared to the nonvolatile semiconductor memory device according to related art.

Particularly, in the case where excess holes are formed in the part of the charge accumulation layer on the first gate electrode 5 side under the second gate electrodes 4 and 6, the excess holes formed in the part of the charge accumulation layer can be reduced with use of Step 2, thus improving the retention characteristics.

It should be noted that, in the case of erasing the nonvolatile semiconductor memory with use of Step 1 and Step 2, Step 4 (determination of an erase level) may be performed after Step 1 and Step 2, or Step 4 may be omitted.

### Second Exemplary Embodiment

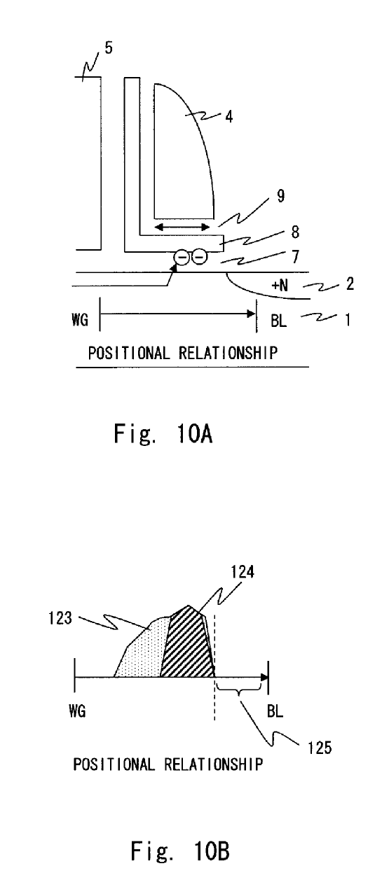

Another exemplary embodiment of the present invention is described hereinafter with reference to the drawings. Firstly, a nonvolatile semiconductor memory device for implementing an erase method of a nonvolatile semiconductor memory device according to the exemplary embodiment is described hereinafter with reference to FIG. 10A. In the nonvolatile semiconductor memory device shown in FIG. 10A, the widths of the control gate CG1 and the charge accumulation layer 8 are narrower compared to the nonvolatile semiconductor memory device according to the first exemplary embodiment shown in FIG. 2. Specifically, in the nonvolatile semiconductor memory device according to the exemplary embodiment, the memory cell is scaled down by improvement of scaling process technology, and the widths of the control gate CG1 and the charge accumulation layer 8 become smaller accordingly. The other elements are the same as those in the nonvolatile semiconductor memory device according to the first exemplary embodiment and thus not redundantly described.

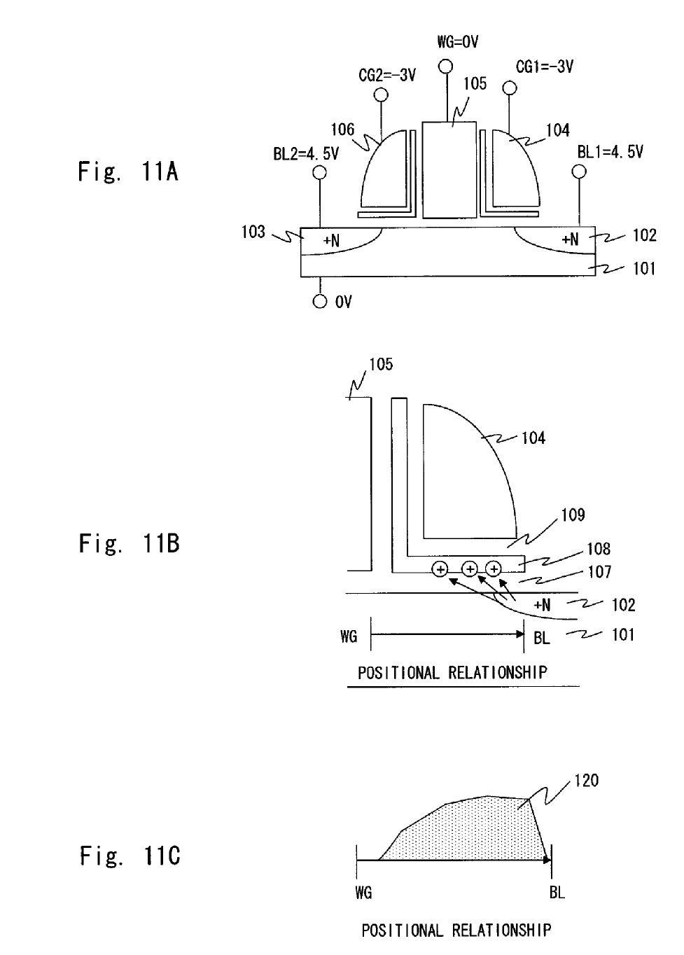

The case where holes and electrons are injected into the nonvolatile semiconductor memory device according to the exemplary embodiment is described hereinbelow. FIG. 10B is a distribution view of holes and electrons when holes and electrons are injected into the nonvolatile semiconductor memory device according to the exemplary embodiment having the structure shown in FIG. 10A. In FIG. 10B, 123 denotes distribution of holes, and 124 denotes distribution of electrons. Comparing the hole distribution 123 of FIG. 10B with the hole distribution 120 of FIG. 11C described in related art, holes are not accumulated on the BL side 125 because the length of the charge accumulation layer 8 is smaller by scaling-down of the memory cell size and the charge accumulation layer 8 does not exist in a BL side 125 in this exemplary embodiment.

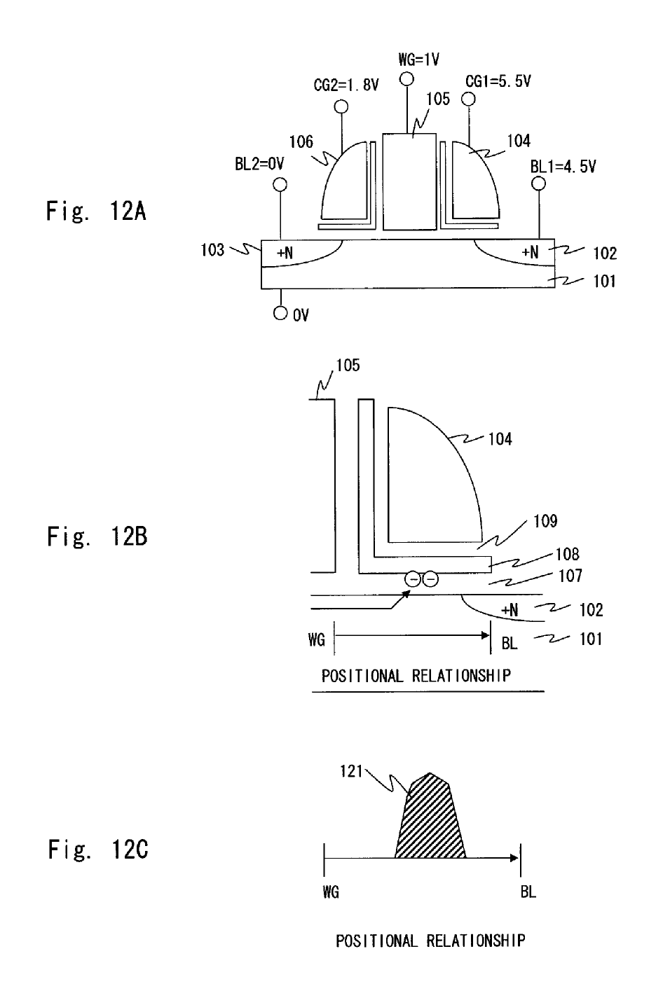

On the other hand, in FIG. 10B, the electron distribution 124 is similar to the electron distribution 121 in FIG. 12C described in related art. In the case of distribution of holes and electrons shown in FIG. 10B, the position of the electron distribution 124 and the position on the BL side of the hole distribution 123 upon normal writing substantially overlap. In such a case, there would be no need to consider the effect of the excess distribution 131 on the BL side shown in FIG. 13 described in related art.

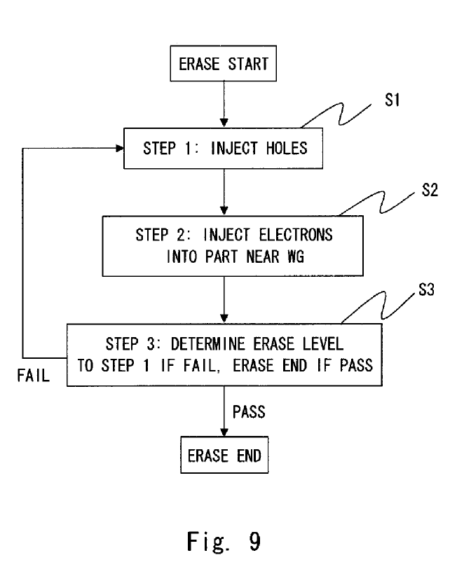

Thus, in the erase method of the nonvolatile semiconductor memory device according to the exemplary embodiment having the structure as shown in FIG. 10A, injection of electrons into the part near BL described in the first exemplary embodiment (Step 3 in the first exemplary embodiment) can be omitted. FIG. 9 shows the erase method of the nonvolatile semiconductor memory device according to the exemplary embodiment.

In the erase method according to the exemplary embodiment, hot holes are injected into the charge accumulation layer from the diffusion region (S1: Step 1). Step 1 is the same as the one described in the first exemplary embodiment and not redundantly described.

Next, weak writing, i.e. injection of electrons, is performed in the part of the charge accumulation layer 8 close to the WG side (S2: Step 2). Step 2 is also the same as the one described in the first exemplary embodiment and not redundantly described.

Then, in Step 3 (S3) according to the exemplary embodiment, an erase level, i.e. the amount of holes accumulated in the charge accumulation layer, after performing the erase steps of Step 1 and Step 2 is determined by measuring a read current in the memory cell. If the erase level is insufficient, the process returns to Step 1 and starts the erase step again. If, on the other hand, it is determined that the erase level is sufficient, the process ends the erase work.

In this exemplary embodiment of the present invention also, determination of an erase level (Step 3) is not an essential step. Thus, Step 3 can be omitted by using a method that presets the number of times of repeating Step 1 and Step 2 so as to reach a sufficient erase level, for example.

By the erase method of the nonvolatile semiconductor memory device according to the exemplary embodiment, it is possible to reduce formation of excess holes in the charge accumulation layer and thereby provide the nonvolatile semiconductor memory device with suitable retention characteristics. Particularly, in the erase method of the nonvolatile semiconductor memory device according to the exemplary embodiment, injection of electrons into the area near BL can be omitted, thus enabling erase of the nonvolatile semiconductor memory device in a shorter time.

The present invention is widely applicable to a technical field such as electronic equipment using a nonvolatile semiconductor memory device.

While the invention has been described in terms of several exemplary embodiments, those skilled in the art will recognize that the invention can be practiced with various modifications within the spirit and scope of the appended claims and the invention is not limited to the examples described above.

Further, the scope of the claims is not limited by the exemplary embodiments described above.

Furthermore, it is noted that, Applicant's intent is to encompass equivalents of all claim elements, even if amended later during prosecution.

What is claimed is:

1. An erase method of a nonvolatile semiconductor memory device, the nonvolatile semiconductor memory device including a semiconductor substrate with diffusion regions spaced from each other, a first insulating layer formed on the semiconductor substrate, a first gate electrode formed in a first area on the first insulating layer, a charge accumulation layer formed in a second area on the first insulating layer, a second insulating layer formed on the charge accumulation layer, and a second gate electrode formed on the second insulating layer, the method comprising steps of:
injecting hot holes into the charge accumulation layer from the diffusion region; and
injecting channel hot electrons into a part of the charge accumulation layer close to the first gate electrode side.

2. The erase method of a nonvolatile semiconductor memory device according to claim 1, further comprising a step of:
injecting channel hot electrons into a part of the charge accumulation layer close to a drain region side.

3. The erase method of a nonvolatile semiconductor memory device according to claim 1, further comprising a step of:
determining charges in the charge accumulation layer after the steps of injecting hot holes and injecting channel hot electrons into the charge accumulation layer.

4. The erase method of a nonvolatile semiconductor memory device according to claim 1, wherein
in the step of injecting hot holes into the charge accumulation layer from the diffusion region, a voltage applied to the diffusion region is set to be higher than a voltage applied to the second gate electrode.

5. The erase method of a nonvolatile semiconductor memory device according to claim 1, wherein
in the step of injecting channel hot electrons into a part of the charge accumulation layer close to the first gate electrode side, a voltage applied to a drain region is set to be lower than a voltage applied to the second gate electrode.

6. The erase method of a nonvolatile semiconductor memory device according to claim 2, wherein
in the step of injecting channel hot electrons into a part of the charge accumulation layer close to the drain region side, a voltage applied to the drain region is set to be lower than a voltage applied to the second gate electrode.

7. The erase method of a nonvolatile semiconductor memory device according to claim 6, wherein
a difference between the voltage applied to the drain region and the voltage applied to the second gate electrode in the step of injecting channel hot electrons into a part of the charge accumulation layer close to the first gate electrode side is larger than a difference between the voltage applied to the drain region and the voltage applied to the second gate electrode in the step of injecting channel hot electrons into a part of the charge accumulation layer close to the drain region side.

8. The erase method of a nonvolatile semiconductor memory device according to claim 1, wherein
injection of channel hot electrons into the charge accumulation layer is performed with a lower voltage than a voltage in injection of channel hot electrons in normal write operation.

9. The erase method of a nonvolatile semiconductor memory device according to claim 1, wherein
injection of channel hot electrons into the charge accumulation layer is performed for a shorter time than a time of injection of channel hot electrons in normal write operation.
